(19) United States
(12) Patent Application Publication
(10) Pub. No.: US 2009/0253241 A1
(43) Pub. Date: Oct. 8, 2009

(54) METHOD FOR MANUFACTURING A SEMICONDUCTOR DEVICE

(75) Inventor: Hyoung Ryeun Kim, Uiwang-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/342,920

(22) Filed: Dec. 23, 2008

(30) Foreign Application Priority Data
Apr. 3, 2008 (KR) 10-2008-0031320

(51) Int. Cl. H01L 21/467; H01L 21/463; H01L 21/76

(52) U.S. Cl. 438/424; 438/692; 257/E21.484; 257/E21.486; 257/E21.54

(57) ABSTRACT

Disclosed herein is a method for manufacturing a semiconductor device that includes: etching a semiconductor substrate to form a recess region; forming a device isolation trench in a portion of the etched semiconductor substrate including a portion of the recess region; and forming a device isolation film in the device isolation trench. The recess region is formed before the device isolation film, which can prevent a gate subsequently formed over the device isolation film from leaning. As a result, a subsequent landing plug contact hole is opened, which can improve process defects.

### CROSS-REFERENCE TO RELATED APPLICATION

Priority to Korean patent application number 10-2008-0031320, filed on Apr. 3, 2008, the disclosure of which is incorporated by reference in its entirety, is claimed.

### BACKGROUND OF THE INVENTION

1. Field of the Disclosure

The invention generally relates to a method for manufacturing a semiconductor device, and more specifically, to a method for manufacturing a semiconductor device that includes forming a recess region before forming a device isolation film. The manufacturing method can prevent a gate formed over the device isolation film from leaning. As a result, a subsequent landing plug contact hole can be opened, which can minimize process defects.

2. Brief Description of Related Technology

A method for isolating elements of a semiconductor device generally includes performing a local oxidation of silicon (LOCOS) method and a trench isolation method.

In the LOCOS method, the process is simple, and a broad portion of the silicon substrate and a narrow portion of the silicon substrate can be isolated simultaneously. However, a bird's beak is formed by a side oxidation process used to enlarge the width of a device isolation region, thereby reducing the effective area of source/drain regions.

When a field oxide film is formed, a stress caused by the difference of the thermal expansion coefficients is concentrated on the edge of the oxide film. As a result, a crystal defect is generated in a silicon substrate, which causes a leakage current.

In the trench isolation method, a trench is formed in the silicon substrate, and an insulating material such as an oxide is filled in the trench, thereby enlarging the effective isolation length in the same isolation width. As a result, a smaller isolation region can be obtained than in the LOCOS method.

Of various device isolation techniques using a trench, it is important to control formation of the profile of the trench in order to obtain a device having a stable characteristic.

It is important to properly determine the trench depth, the trench angle, and the trench edge shape. Specifically, when a shallow trench isolation (STI) method is used in a high-integrated semiconductor device, an electric characteristic of the device depends on the profile of the edge of the trench.

FIGS. 1 to 7 are diagrams illustrating a conventional method for manufacturing a semiconductor device. In the figures, (a) is a plan view, and (b) is a cross-sectional view taken along A-A′ of (a).

Referring to FIG. 1, a first photoresist film (not shown) is formed over a semiconductor substrate 100. The first photoresist film is exposed and developed using a device isolation mask (not shown) to form a first photoresist pattern 102. A portion of the semiconductor substrate 100 is etched using the first photoresist pattern 102 as an etching mask to form a device isolation trench 104.

Referring to FIG. 2, the first photoresist pattern 102 is removed. A device isolation insulating film 106 is formed over the semiconductor substrate 100 including the device isolation trench 104. The device isolation insulating film 106 includes an oxide film.

Referring to FIG. 3, the device isolation insulating film 106 is planarized to expose a portion of the semiconductor substrate 100, thereby forming a device isolation film 106a to define an active region 108.

Referring to FIG. 4, a second photoresist film (not shown) is formed over the semiconductor substrate 100 including the device isolation film 106a. The second photoresist film is exposed and developed using a mask (not shown) that defines a gate-expected region, thereby forming a second photoresist pattern 110.

Referring to FIG. 5, the semiconductor substrate 100 is etched using the second photoresist pattern 110 as an etching mask, thereby forming a recess region 112. The second photoresist pattern 110 is removed. As a result of an etching selectivity difference between the active region 108 and the device isolation film 106a, the recess region 112 formed over the device isolation film 106a is formed shallower than the recess region 112 formed over the active region 108.

In order to eliminate the etching residual generated in formation of the recess region 112, a washing process is performed on the semiconductor substrate 100 including the recess region 112. As shown in (c) of FIG. 5, a widening phenomenon (B) occurs where the width of the recess region 112 formed over the device isolation film 106a is widened.

Referring to FIG. 6, a gate insulating film (not shown) is formed over the semiconductor substrate 100 including the recess region 112. A gate polysilicon layer 114, a gate electrode layer 116, and a gate hard mask layer 118 are formed over the gate insulating film.

The gate electrode layer 116 includes a tungsten (W) layer. The gate hard mask layer 118 includes a nitride film. A third photoresist film (not shown) is formed over the gate hard mask layer 118. The third photoresist film is exposed and developed using a gate mask (not shown) to form a third photoresist pattern 120.

Referring to FIG. 7, the gate hard mask layer 118, the gate electrode layer 116, and the gate polysilicon layer 114 are etched using the third photoresist pattern 120 as an etching mask. As a result, a gate 122 is obtained, which includes a gate hard mask pattern 118a, a gate electrode pattern 116a, and a gate polysilicon pattern 114a.

As shown in FIG. 7b, the width of the recess region formed over the device isolation film 106a is larger than that of the gate 122. As a result, the gate 122 formed over the device isolation film 106a leans (C). This leaning can cause a landing plug contact hole not to open in a subsequent landing plug process, which can cause a device defect.

### BRIEF SUMMARY OF THE INVENTION

Various embodiments of the invention are directed to providing a method for manufacturing a semiconductor device that includes forming a recess region before a device isolation film, which can prevent a gate formed over the device isolation film from leaning. As a result, a subsequent landing plug contact hole can be opened, thereby improving process defects.

According to an embodiment of the invention, a method for manufacturing a semiconductor device includes: etching a semiconductor substrate to form a recess region; forming a device isolation trench in a portion of the etched semiconductor substrate including a portion of the recess region; and forming a device isolation film in the device isolation trench.

The device isolation trench can be formed by forming a photoresist pattern that exposes a predetermined region of the etched substrate where the device isolation trench is to be formed, and etching the predetermined region with the photoresist pattern as an etching mask to form the device isolation trench. The photoresist pattern can be formed by forming a photoresist film over the etched semiconductor substrate, and exposing and developing the photoresist film using a device isolation mask that defines an active region. The active region can be formed, for example, to be a G type, an I type, a T type, and combinations thereof.

The exposing process can be performed, for example, using a light source selected from KrF, ArF, I-line, and combinations thereof.

The device isolation film can be formed by forming an insulating film over the photoresist pattern and the device isolation trench, and planarizing the insulating film to expose the semiconductor substrate and thereby form the device isolation film. The device isolation film can include, for example, an insulating film.

The planarizing process can be performed by a chemical mechanical polishing (CMP) method, an etch-back method, and combinations thereof.

The recess region can be, for example, a recess region type selected from the group consisting of a line type, a wave type, and combinations thereof.

The insulating film can include, for example, an oxide film.

After forming the device isolation film, the method can further include: forming a gate insulating film over the semiconductor substrate including the recess; forming a gate polysilicon layer, a gate electrode layer, and a gate hard mask layer over the gate insulating film; and etching the gate hard mask layer, the gate electrode layer, and the gate polysilicon layer using a photo-etching process using a gate mask to form a gate.

### BRIEF DESCRIPTION OF THE DRAWINGS

For a more complete understanding of the disclosure, reference should be made to the following detailed description and accompanying drawings.

FIGS. 1 to 7 are diagrams illustrating a conventional method for manufacturing a semiconductor device.

FIGS. 8 to 13 are diagrams illustrating a method for manufacturing a semiconductor device according to an embodiment of the invention. FIGS. 8a-13a are plan views and FIGS. 8b-13b are cross-sectional views taken along line D-D′.

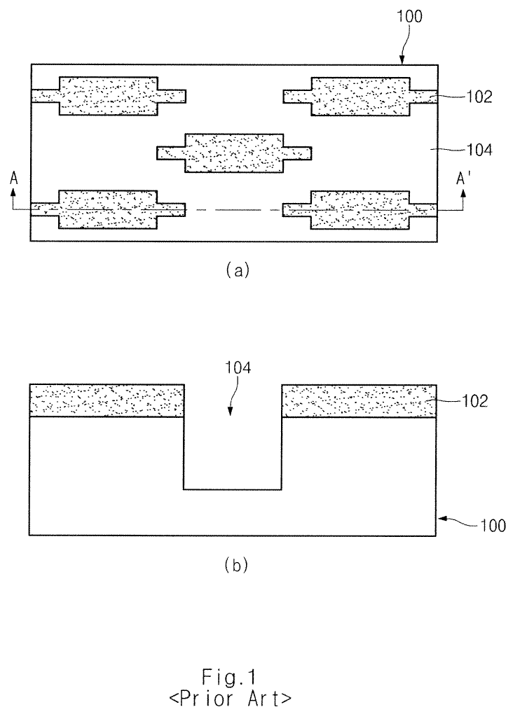

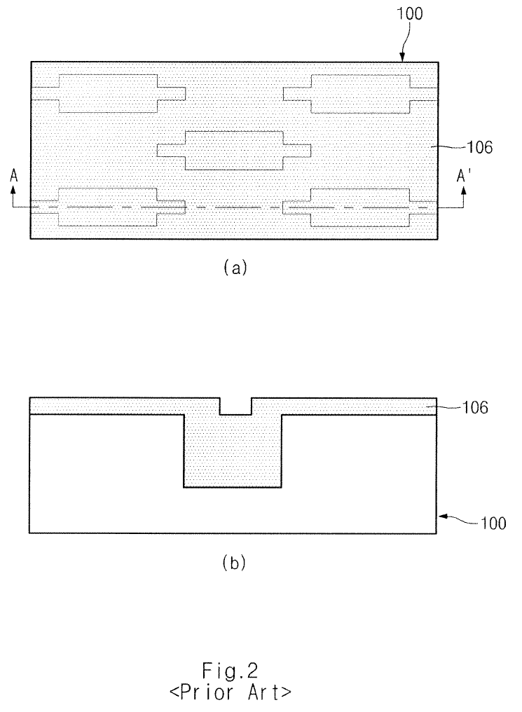

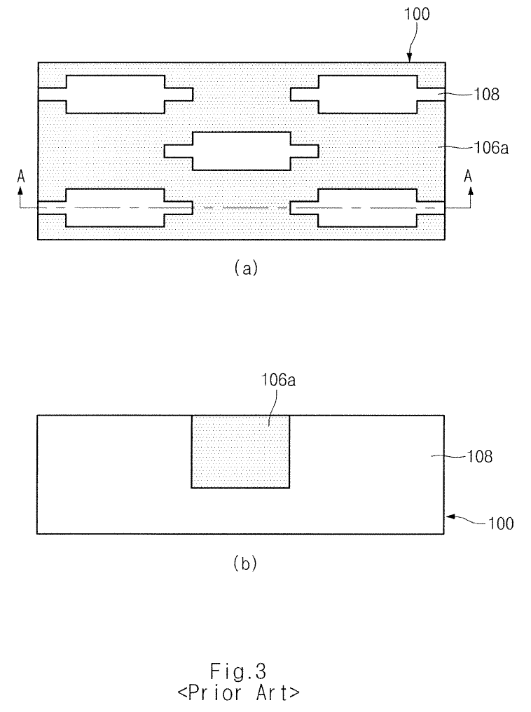

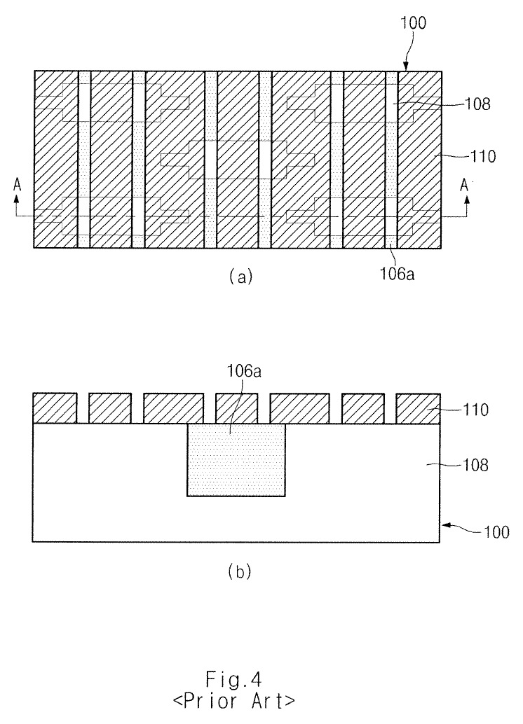

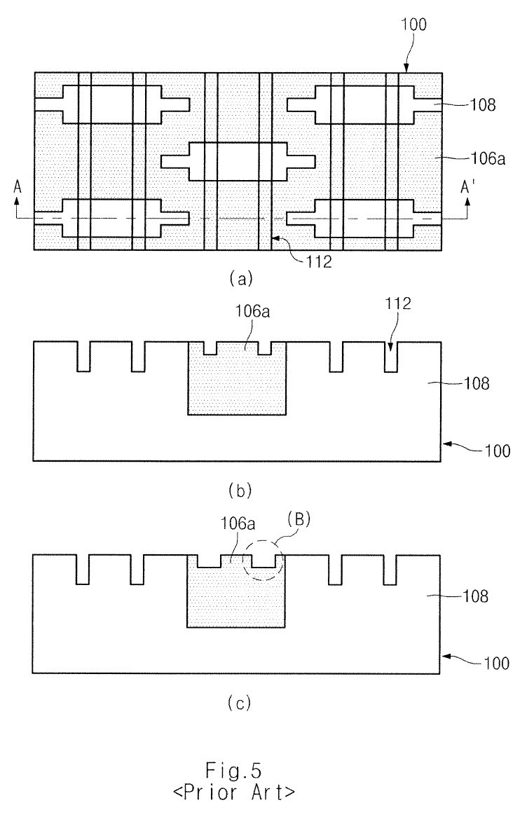

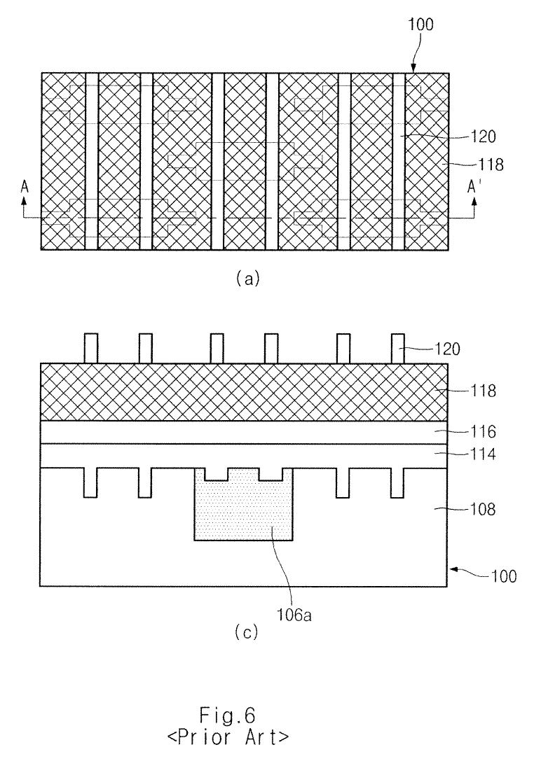

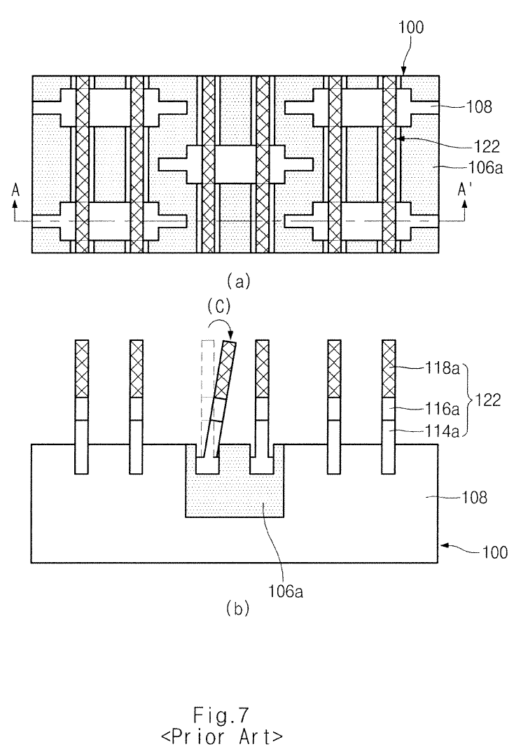

While the disclosed method is susceptible of embodiments in various forms, specific embodiments are illustrate in the drawings (and will hereafter be described), with the understanding that the disclosure is intended to be illustrative, and is not intended to limit the invention to the specific embodiments described and illustrated herein.

### DESCRIPTION OF SPECIFIC EMBODIMENTS

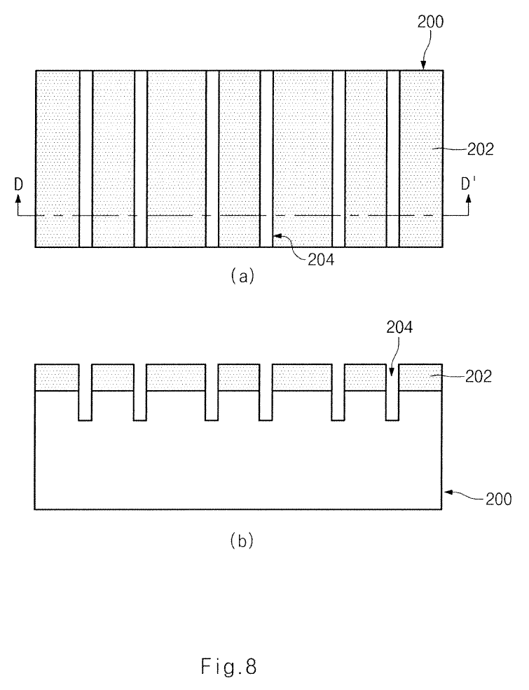

Referring to FIG. 8, a first photoresist film (not shown) is formed over a semiconductor substrate 200. The first photoresist film is exposed and developed using a mask (not shown) that defines a gate-expected region, thereby forming a first photoresist pattern 202.

The first photoresist film can be exposed, for example, using a light source selected from the group consisting of KrF (248 nm), ArF (193 nm), I-line (365 nm), and combinations thereof. An antireflection film (not shown) can be formed over the semiconductor substrate 200 before forming the first photoresist film.

The semiconductor substrate 200 is etched using a first photoresist pattern 202 as an etching mask to form a recess region 204. The recess region 204 can be formed, for example, to be a line or wave type recess region 204.

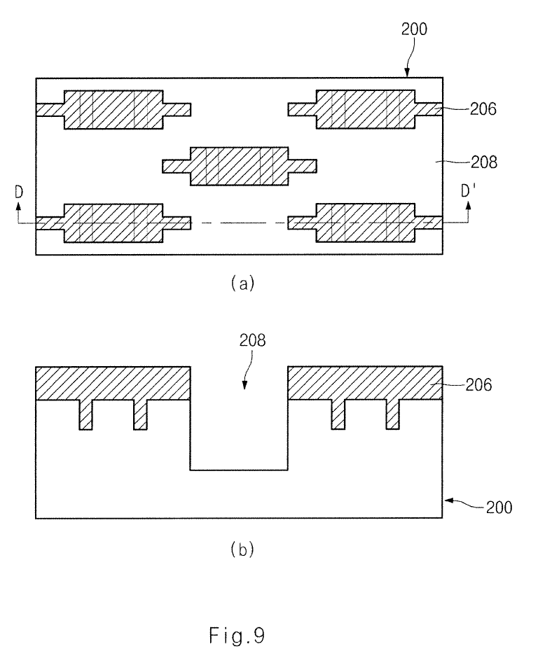

Referring to FIG. 9, the first photoresist pattern 202 is removed, and a second photoresist film (not shown) is formed over the semiconductor substrate 200 including the recess region 204. The second photoresist film is exposed and developed using a device isolation mask (not shown), thereby forming a second photoresist pattern 206.

The device isolation mask defines an active region. The active region can be, for example, a G type active region, an I-type active region, a T type active region, and combinations thereof. The second photoresist film can be exposed, for example, using a light source selected from the group consisting of KrF, ArF, I-line, and combinations thereof.

The semiconductor substrate 200 is etched using the second photoresist pattern 206 as an etching mask to form a device isolation trench 208.

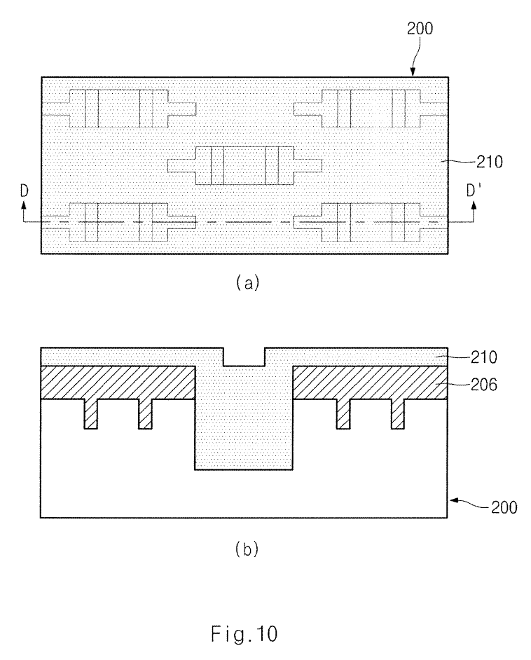

Referring to FIG. 10, a device isolation insulating film 210 is formed over the second photoresist pattern 206 including the device isolation trench 208. The device isolation insulating film 210 can include, for example, an oxide film.

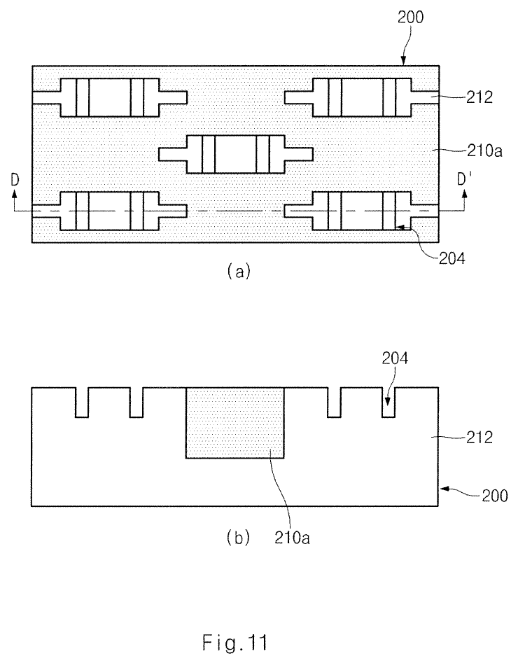

Referring to FIG. 11, the device isolation insulating film 210 and the second photoresist pattern 206 are planarized to expose the semiconductor substrate 200, thereby forming a device isolation film 210a, which defines an active region 212.

The device isolation insulating film 210 and the second photoresist pattern 206 can be planarized by a chemical mechanical polishing (CMP) method, an etch-back method, and combinations thereof.

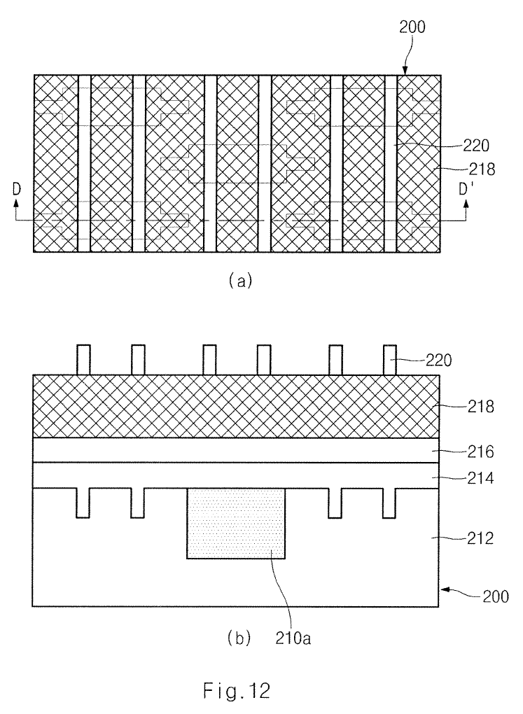

Referring to FIG. 12, a gate insulating film (not shown) is formed over the semiconductor substrate 200 including the recess region 204. A gate polysilicon layer 214, a gate electrode layer 216, and a gate hard mask layer 218 are formed over the gate insulating film.

The gate electrode layer 216 can include, for example, a tungsten (W) layer. The gate hard mask layer 218 can include, for example, a nitride film. A third photoresist film (not shown) is formed over the gate hard mask layer 218. The third photoresist film is exposed and developed using a gate mask to form a third photoresist pattern 220.

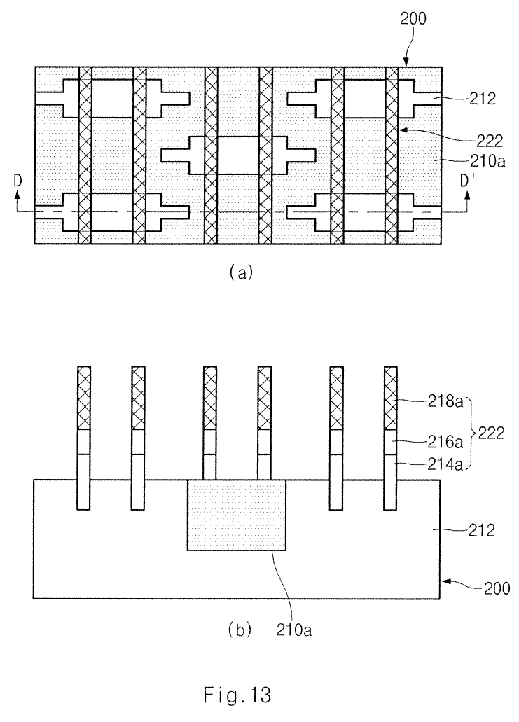

Referring to FIG. 13, the gate hard mask layer 218, the gate electrode layer 216, and the gate polysilicon layer 214 are etched using the third photoresist pattern 220 as an etching mask. As a result, a gate 222 including a gate hard mask pattern 218a, a gate electrode pattern 216a, and a gate polysilicon pattern 214a is formed.

As described above, according to an embodiment of the invention, a recess region 204 is formed before a device isolation film 210a, so that the recess region 204 remains only in an active region. Since there is no recess region 204 on the device isolation film 210a, it is possible to prevent a gate 222 formed over the device isolation film 210a from leaning.

The above embodiments of the disclosure are illustrative and not limitative. Various alternatives and equivalents are possible. The invention is not limited by the type of deposition, etching polishing, and patterning steps describe herein. Nor is the invention limited to any specific type of semiconductor device. For example, the disclosure may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
etching a semiconductor substrate to form a recess region;
forming a device isolation trench in a portion of the etched semiconductor substrate including a portion of the recess region; and
forming a device isolation film in the device isolation trench.

2. The method according to claim 1, wherein formation of the device isolation-trench comprises
forming a photoresist pattern that exposes a predetermined region of the etched substrate where the device isolation trench is to be formed; and,
etching the predetermined region using the photoresist pattern as an etching mask to form the device isolation trench.

3. The method according to claim 2, wherein formation of the photoresist pattern comprises
forming a photoresist film over the etched semiconductor substrate; and,
exposing and developing the photoresist film using a device isolation mask that defines an active region.

4. The method according to claim 3, wherein the active region is an active region type selected from the group consisting of a G type, an I type, a T type, and combinations thereof.

5. The method according to claim 3, wherein the photoresist film is exposed by a light source selected from the group consisting of KrF, ArF, I-line, and combinations thereof.

6. The method according to claim 2, wherein formation of the device isolation film comprises
forming an insulating film over the photoresist pattern and the device isolation trench; and,
planarizing the insulating film and the photoresist pattern to expose the semiconductor substrate.

7. The method according to claim 6, wherein the planarizing process is performed by a process selected from the group consisting of a chemical mechanical polishing (CMP) method, an etch-back method, and combinations thereof.

8. The method according to claim 1, wherein the device isolation film comprises an insulating film.

9. The method according to claim 8, wherein the insulating film comprises an oxide film.

10. The method according to claim 1, wherein the recess region is fa recess region type selected from the group consisting of a line type, a wave type, and combinations thereof.

11. The method according to claim 1 further comprising, following formation of the device isolation film:
forming a gate insulating film over the semiconductor substrate including the recess;
forming a gate polysilicon layer, a gate electrode layer, and a gate hard mask layer over the gate insulating film; and
photo-etching the gate hard mask layer, the gate electrode layer, and the gate polysilicon layer using a gate mask to form a gate.
